(19) United States
(12) Patent Application Publication
(10) Pub. No.: US 2008/0268632 A1
(43) Pub. Date: Oct. 30, 2008

(54) LED epiwafer pad manufacturing process & new construction thereof

(75) Inventors: Song- Ping Luh, HSIP Hsinchu (TW); Chiang Jung Hwa, Tahsi Town (TW); Ming- Shun Lee, Taipei (TW)

Correspondence Address: TROXELL LAW OFFICE PLLC, SUITE 1404, 5205 LEESBURG PIKE, FALLS CHURCH, VA, 22041, US

(73) Assignee: FuPo Electronics Corporation.

(21) Appl. No.: 11/797,095

(22) Filed: Apr. 30, 2007

(51) Int. Cl. H01L 21/44

(52) U.S. Cl. 438/612; 257/E21.476

(57) ABSTRACT

A pad manufacturing process applied in LED epiwafer and a new construction thereof comprising of a means to increase interfacial bonding strength being provided first to the surface of the epiwafer; followed with a metal deposition means provided to the surface of the epiwafer by having the surface processed with plasma to improve adhesion between pad and epiwafer; and plating conditions being controlled to obtain finer and more uniform grains to correct the problem of pad surface roughness in order to improve the bonding strength between pad and bonding wire. Furthermore, a new construction of epiwafer and a pad is comprised of an epiwafer containing a substrate, an epitaxial layer, and a first metal layer covering the top of the epitaxial layer; an adhesion layer covering the top of the first metal layer; and a pad covering the top of the adhesion layer in sequence.

### BACKGROUND OF THE INVENTION

(a) Field of the Invention

The present invention is related to a semiconductor manufacturing process and a new construction thereof, and more particularly, to one that is applied in the pad manufacturing process of LED epiwafer and a new construction thereof.

(b) Description of the Prior Art

As illustrated in FIG. 1 of the accompanying drawings, a pad 12 in a given thickness using a semiconductor manufacturing process is deposited to a metal layer 11 serving as an electrode in an LED epiwafer 10 of the prior art to prevent destruction of construction and affected electricity due to significant impacts against the epiwafer 10 as a wire 13 is bonded to the pad 12 during wire bonding.

The production modes of the LED electronic industry today feature that:
1. The evaporation process is followed the completion of the metal layer 11 in the same fab by the chipmaker to complete the bond pad 12. However, this mode is found with the following flaws:
   a. Peel-off between the metal layer 11 and the bond pad; and
   b. Poor efficiency of the use of precious metal (gold) and comparatively higher production cost incurred from the evaporation process.
2. Upon completing the manufacturing process of the metal layer 11, the chipmaker has the process of making the bond pad 12 to be completed by a subcontractor; accordingly, the subcontractor may apply either one of the following processes:
   a. Complete the bond pad 12 directly on the metal layer 11 in the electroplating process since the electroplating process provides better efficiency than that of evaporation; or
   b. Complete the photo process and then complete the electroplating process at the designated locations to further improve the utilization efficiency of the gold.
      In either process of 2-a or 2-b, however, the peel-off problem resulted from poor adhesion between the metal layer 11 and the bond pad 12 still occur occasionally.

Furthermore, the bonding strength between the pad 12 and the wire 13 is deteriorated by the rough surface of the pad 12. In the prior art, the problem of the rough surface of the pad 12 as the result of the plating process could be compensated by higher bonding force during wire bond to smear the uneven gold grains to obtain the flatter surface and facilitate the gold-gold inter-diffusion in the wire bonding. But the higher bonding force could easily damage the structure underneath the pads because of the fragile nature of the LED material.

### SUMMARY OF THE INVENTION

The primary purpose of the present invention is to provide a pad manufacturing process applied in LED epiwafer essentially comprised of the following steps:
(A) An epiwafer is prepared and formed on its surface a first metal layer;
(B) A means to increase interfacial bonding strength is performed on the surface of the first metal layer;
(C) A second metal layer is deposited on the surface of the first metal layer; and
(D) A pad is patterned on the surface of the epiwafer by using the photolithography method.

Wherein, the means to increase interfacial bonding strength may be related to any of the following means:
(1) Surface cleaning means: including physical way (e.g., plasma process, wipe to clear with yarn or woven fabric, wipe to clean with ultra refine fiber yarn or woven fabric); chemical way (e.g., soaking in or wiping with high purity and high volatility solvents including isopropyl alcohol, and acetone; or soaking in or wiping with etching liquid HCl/HNO₃ solution);
(2) Surface roughening means: physical way (e.g., processed with plasma, sand grinding, sand blasting, or grinding), or chemical way (e.g., placed in erosive gas or liquid, or soaking in or wiping with erosive liquid, low concentration etching liquid HCl/HNO₃); or
(3) Adhesion coating means: a conductive adhesion layer is added to the interface, e.g., coated or deposited with conductive metal including chrome or titanium, or conductive alloy such as Ti—W.

Wherein, the metal deposition means can be done in physical vapor deposition (e.g., evaporation or sputtering), chemical vapor deposition, electroplating, or electroless plating.

Taking the plasma for instance, the first metal surface of the epiwafer is plasma processed; the second metal layer is electroplated on the surface of the first metal layer; and the pad pattern is formed by the photolithography and metal etching processes to To reliably improve the adhesion between the pad and the epiwafer.

A conductive adhesion layer is further provided to be sandwiched between the first and the second metal layers to increase the interfacial bonding strength between the first and the second metal layers while forming a new epiwafer and pad construction.

Furthermore, the roughness of the surface of the electroplated pad is improved by controlling the plating conditions. To obtain finer and more uniform grain size on the pad surface, which subsequently increase the contact surface area between the ball of the gold wire and the pad surface during the wire bonding process, and the bonging strength of the two can be improved thereafter.

### BRIEF DESCRIPTION OF THE DRAWINGS

FIG. 1 is a schematic view showing an LED epiwafer is wire bonded by means of a pad of the prior art.

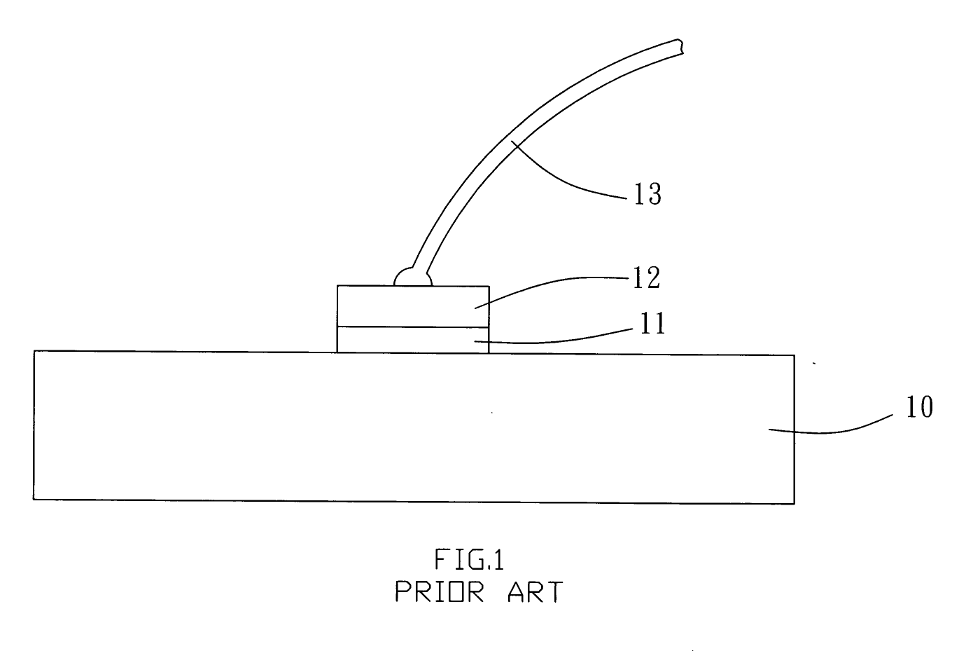

FIG. 2 is a side view showing a pad manufacturing process of a first preferred embodiment of the present invention.

FIG. 3 is a second side view showing the pad manufacturing process of the first preferred embodiment of the present invention.

FIG. 4 is a third side view yet showing the pad manufacturing process of the first preferred embodiment of the present invention.

FIG. 5 is a fourth side view yet showing the pad manufacturing process of the first preferred embodiment of the present invention.

FIG. 6 is a first side view showing a pad manufacturing process of a second preferred embodiment of the present invention.

FIG. 7 is a second side view showing the pad manufacturing process of the second preferred embodiment of the present invention.

FIG. 8 is a third side view yet showing the pad manufacturing process of the second preferred embodiment of the present invention.

FIG. 9 is a fourth side view showing the pad manufacturing process of the second preferred embodiment of the present invention.

FIG. 10 is a side view showing a pad manufacturing process of a third preferred embodiment of the present invention.

FIG. 11 is a side view showing a pad manufacturing process of a fourth preferred embodiment of the present invention.

FIG. 12 is a side view showing a new construction of an epiwafer and a pad.

FIG. 13 is a side view of another new construction of an epiwafer and a pad of a fifth preferred embodiment of the present invention.

FIG. 14 is a side view of another new construction of an epiwafer and a pad of a sixth preferred embodiment of the present invention.

### DETAILED DESCRIPTION OF THE PREFERRED EMBODIMENTS

It is to be noted that in the specification, similar elements are assigned with same number.

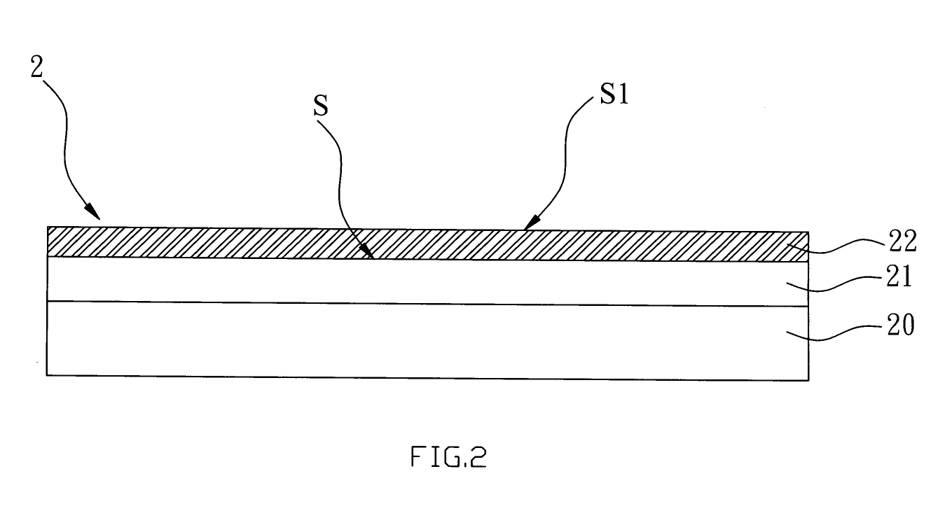

Referring to FIG. 2 for a first preferred embodiment of the present invention related to a manufacturing process of pad applied in an epiwafer LED; an epiwafer 2 including a substrate 20, an epitaxial layer 21 formed on the substrate 20, and a first metal layer 22 formed on a surface S of the epitaxial layer 21 is prepared.

Whereas organic contaminants may be attached to the surface of the first metal layer 22 during its transportation, storage in and leaving warehouse, a cleaning process is needed. To clean the first metal layer 22, a first surface S1 of the first metal layer 22 is first processed with a means to increase its interfacial bonding strength to increase its interfacial bonding strength needed in a subsequent wire bonding process. The means to increase the interfacial bonding strength relates to one to clean the surface in physical way (e.g., processed with plasma, yarns or woven fabric), chemical way (soaking in or wiping with high purity and high volatility solvent including isopropyl alcohol, or acetone, or etching solution HCl/HNO₃) to clean the first surface S1 of the first metal layer 22; or to a surface roughening means in physical way (e.g., processed with plasma, sand grinding, sand blasting or grinding), chemical way (e.g., placement in erosive gas or soaking in or wiping with erosive liquid, low concentration etching solution HCl/HNO₃) to roughen the first surface S1 or the first metal layer 22; or to a coating or deposition of an adhesion layer 31, e.g., an conductive adhesion layer is added to the interface with a coating of a conductive metal including chrome, titanium, or nickel, or an alloy including Ti—W alloy to cover first an adhesive layer to the first surface S1 of the metal layer 22 as to be given detailed description in a third preferred embodiment of the present invention. Wherein, the plasma or the etching solution cleans and roughens the first surface S1 at the same time. Taking oxygen plasma for example, the epiwafer 2 is first placed in an environment containing oxygen plasma for the oxygen plasma to release free radicals of oxygen from the plasma-containing environment by taking advantage of the oxygen; when reacted with those free radicals of oxygen, those organic contaminants enter into gaseous state and clear away from the first surface S1 of the first metal layer 22 for achieving the cleaning purpose.

When argon plasma is used, positive ions of argon in the plasma-containing environment create an ion bombardment on the first surface S1 of the metal layer 22 through negative bias voltage applied underneath the substrate to clean and roughen the first surface S1 of the metal layer 22 at the same time.

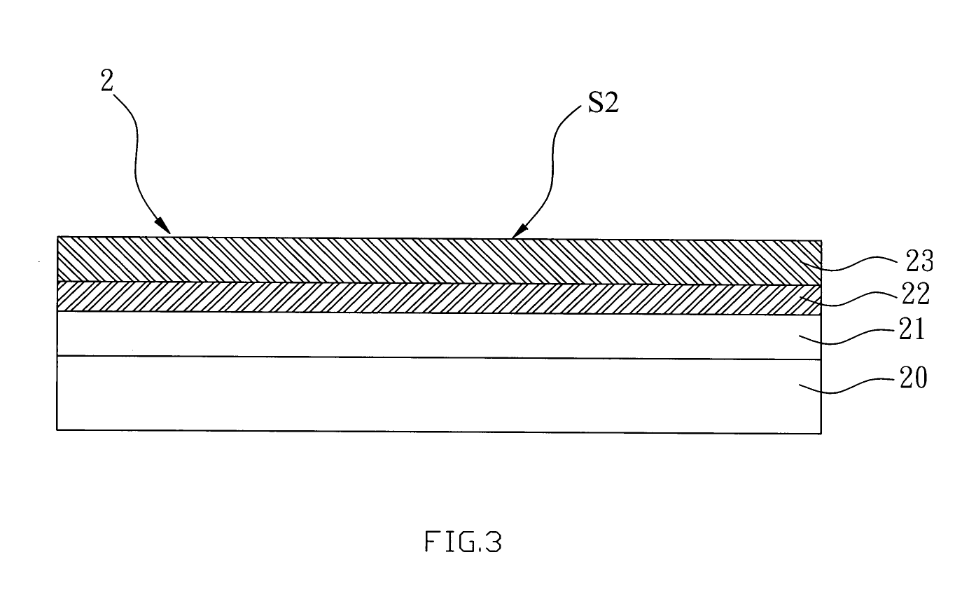

After those organic contaminants are removed from first surface S1 and the first surface is roughened through the plasma process, a second metal layer 23 is deposited by electroplating to become a pad material on the first surface S1.

Wherein, to correct the problem of excessively greater roughness on a second surface S2 of the second metal layer 23 serving as the pad, plating conditions are controlled as illustrated in FIG. 3 by having, fore example, gold plating temperature applied in the prior art lowered to a range of 40˜50° C. and the gold plating current density lowered to where between 0.2˜0.5 Amp/dm² for finer and more uniform grains to be deposited by electroplating to such extent that an arithmetic mean roughness Ra of the central line of the second surface S2 is smaller than 1500 Å.

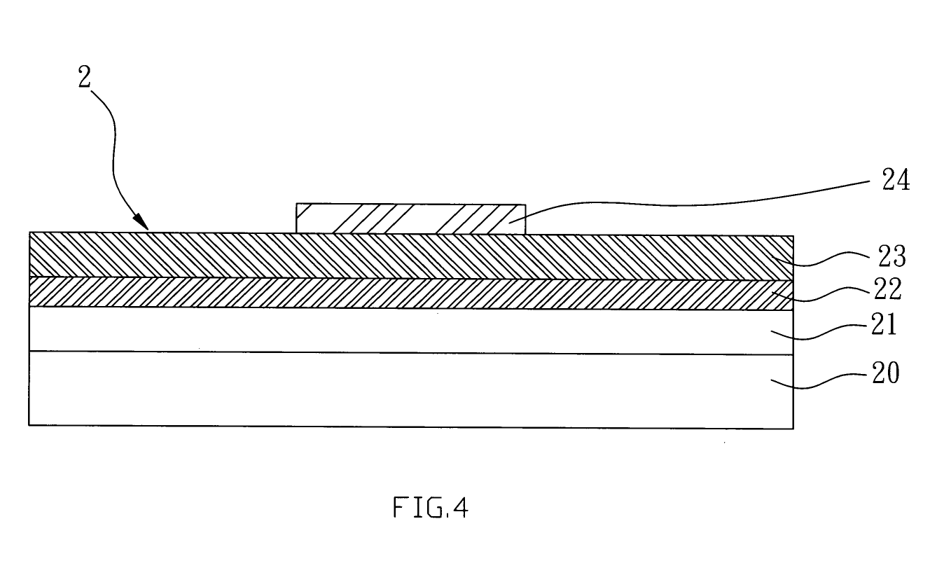

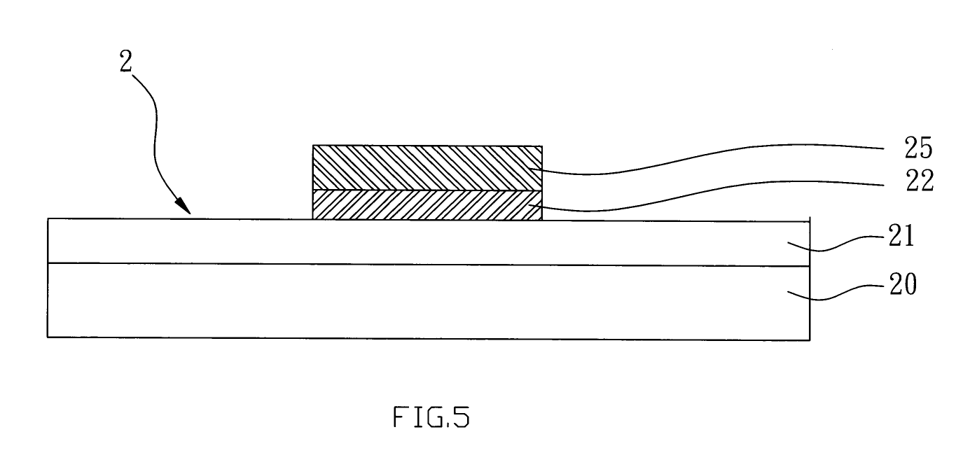

As illustrated in FIG. 4, a photolithography process is applied to form a photo resist mask 24 on the second surface S2 of the second metal layer 23; and an etching process is applied to remove the second metal layer 23 not protected by the photo resist mask 24 and the first metal layer 22 beneath the second metal layer 23; and finally, the photo resist mask 24 is removed to form a pad 25 as illustrated in FIG. 5.

A second preferred embodiment of the pad manufacturing process applied in the LED epiwafer of the present invention in a similar construction of that of the first preferred embodiment as illustrated in FIG. 2 includes an epiwafer 2 containing a substrate 20, an epitaxial layer 21, and a first metal layer 22 formed on a surface S of the epitaxial layer 21.

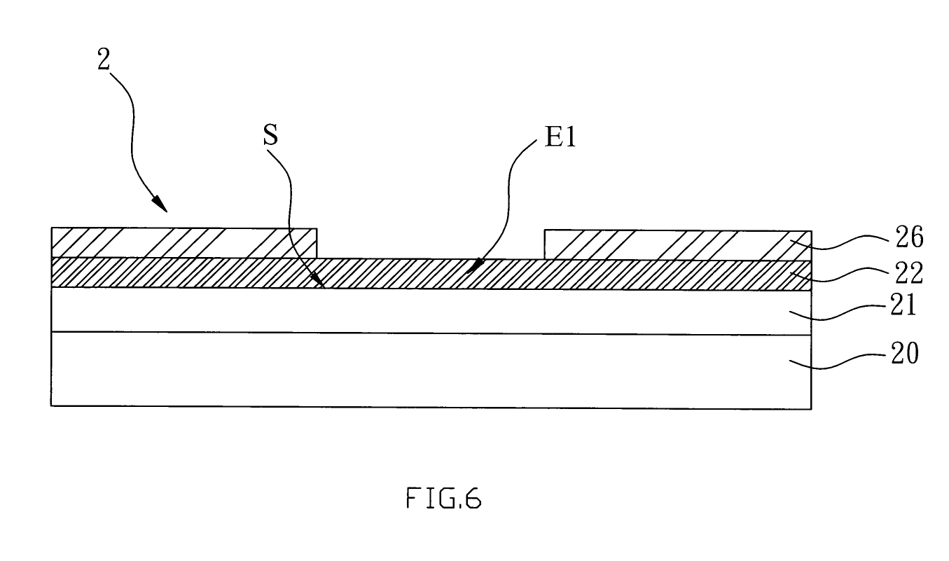

Now referring to FIG. 6, a first photo resist mask 26 is first formed on the first metal layer 22 to define a surface area E1 exposed out of the first metal layer 22. Whereas the surface of the first metal layer in the exposed surface area E1 is attached with organic contaminants during the transportation, storage in and leaving the warehouse of the epiwafer 20, a means to increase the interfacial bonding strength is applied to treat the surface of the first metal layer 22 to increase the bonding strength between the surface of the first metal layer 22 and a pad in future process of wire bonding. The means to increase the interfacial bonding strength is related to a surface cleaning means in physical way (e.g., processed with plasma, yarns or woven fabric, ultra fine fiber yearns or woven fabric), or chemical way (e.g., soaking in or wiping with a solution chemically compatible with the photo resist including diluted HCl/HNO₃) to clean the exposed surface area E1; or to a surface roughening means in physical way (e.g., processed with plasma, sand grinding, sand blasting, or grinding) or chemical way (placement in erosive gas or soaking in or wiping with erosive liquid, low concentration etching solution HCl/HNO₃ that is chemically compatible with the photo resist) to roughen the exposed surface area E1; or to a coating or deposition of an adhesion layer 31, i.e., an addition of a conductive adhesion layer between interfaces by having coated the exposed surface area E1 an adhesion layer of a conductive metal including chrome, titanium, or nickel or an alloy including Ti—W alloy, a process to be given detailed description in a fourth preferred embodiment of the present invention. Wherein, the plasma or the etching liquid cleans and roughens the exposed surface area E1 at the same time. Taking oxygen plasma for example, the plasma process involves placement of the epiwafer 2 with the exposed surface area E1 in a plasma environment containing oxygen for the oxygen to release oxygen free radicals from the plasma-containing environment to react with those organic contaminants; and those organic contaminants are then turned into gaseous state to disengage from the exposed surface area E1 to achieve the purpose of cleaning the exposed surface area E1.

When argon plasma is used, positive ions of argon in the plasma-containing environment create an ion bombardment on the exposed surface area E1 through negative bias voltage, which is applied underneath the substrate to clean and roughen the exposed surface area E1.

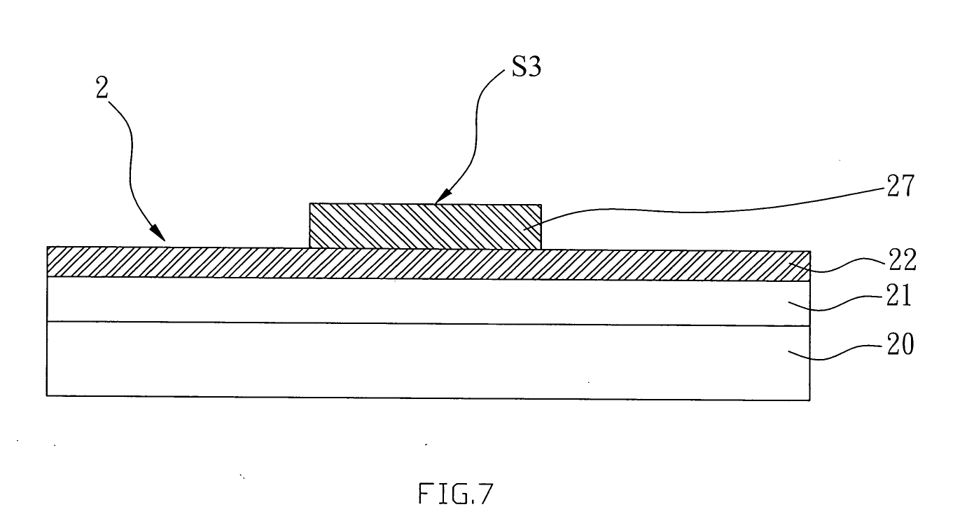

After those organic contaminants are removed from the exposed area E1 and the exposed surface area E1 is roughened through the plasma process, a pad 27 is deposited by electroplating on the exposed surface area E1 and a first photo resist mask 26 is removed as illustrated in FIGS. 6 and 7.

Wherein, to correct the problem of excessive roughness of a third surface S3 of the pad 27 formed by plating, plating conditions are controlled by lowering, for example, the gold plating temperature of the prior art to a range of 40˜50° C., and the gold plating current density to where between 0.2˜0.5 Amp/dm² for finer and more uniform grains are plated by deposition to such extent that an arithmetic mean roughness Ra of the central line of the second surface S2 is smaller than 1500 Å.

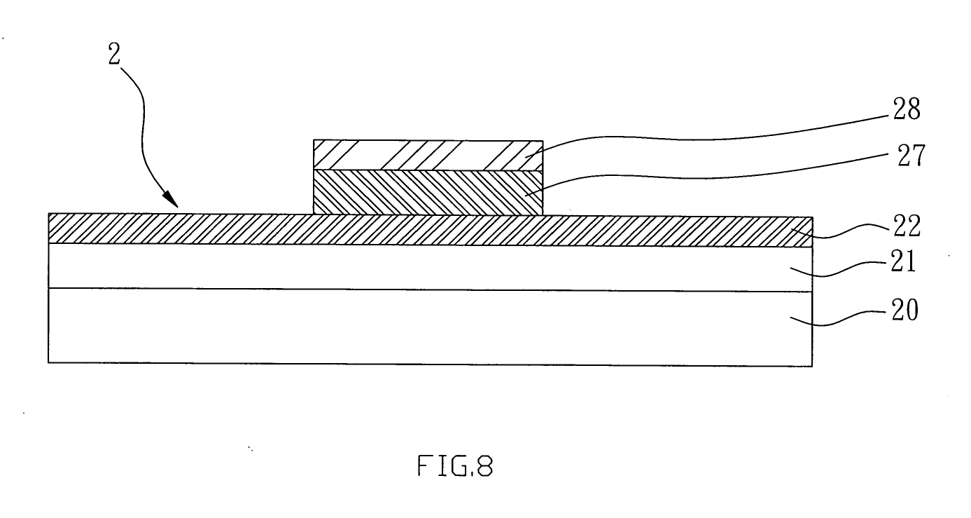

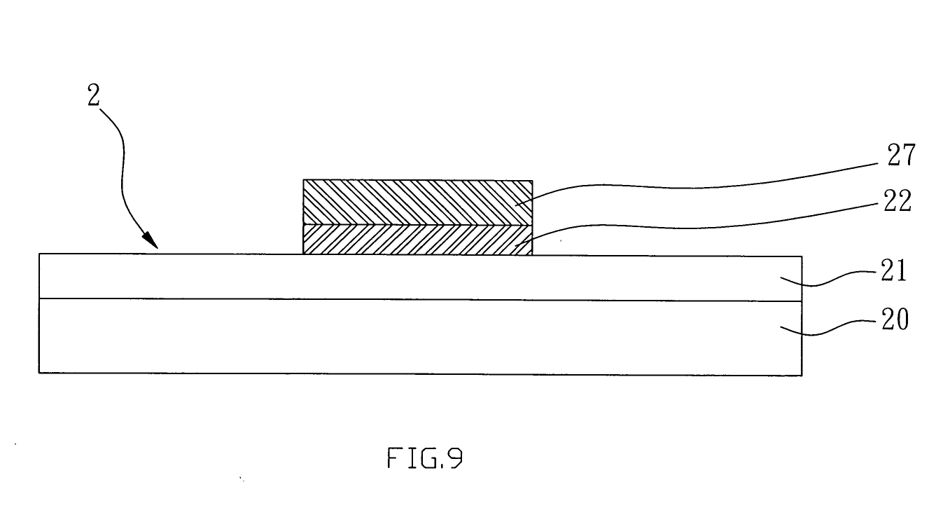

Subsequently as illustrated in FIG. 8, a second photo resist mask 28 in an inverse tone to the first photo resist mask 26 is formed on the third surface S3; and in an etching process, the first metal layer 22 not protected by the second photo resist mask 28 and the pad 27 is removed. The second photo resist mask 28 is then removed to complete the manufacturing process of the pad in the preferred embodiment as illustrated in FIG. 9.

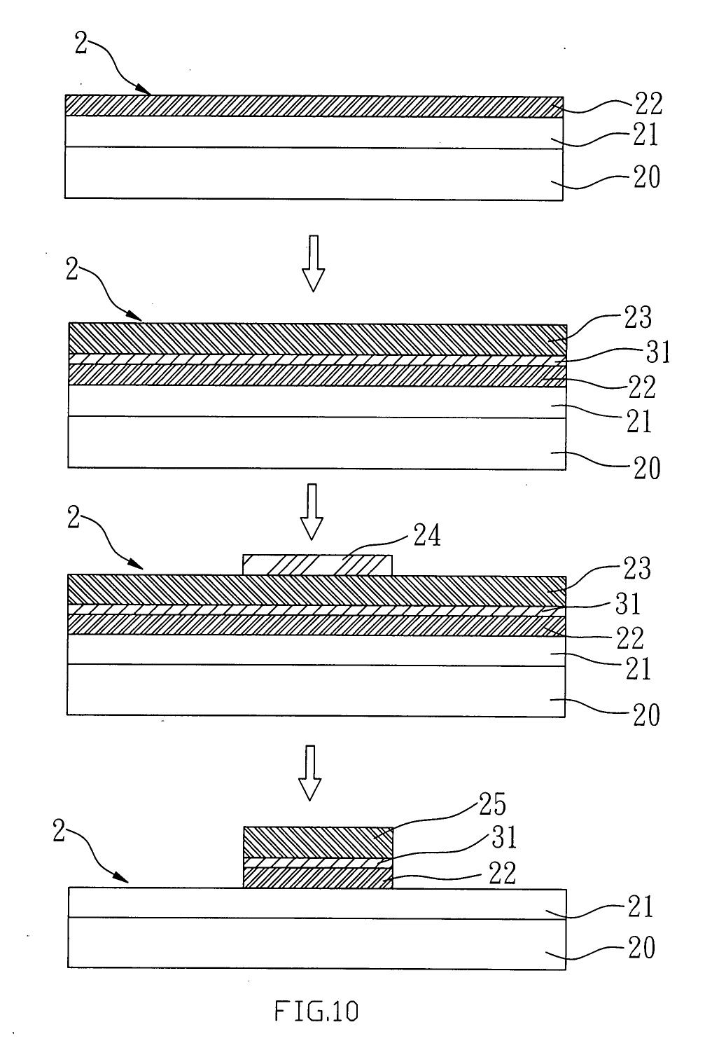

In a manufacturing process sequence as illustrated in FIG. 10 on an adhesion layer 31 coated or deposited in a third preferred embodiment of the present invention for a pad manufacturing process applied in LED epiwafer, the pad manufacturing process of the third preferred embodiment differs from that of the first preferred embodiment in that a second metal layer 23 serving as the pad material is deposited by electroplating on top of the adhesion layer 31; a photo resist mask 24 is formed on a second surface S2 of the second metal layer 23 using a photolithography technique; that the second metal layer 23 not protected by the photo resist mask 24, the adhesion layer 31 below the second metal layer 23 and a first metal layer 22 are removed in an etching process; and finally, the photo resist mask 24 is removed to complete the pad manufacturing process of the third preferred embodiment.

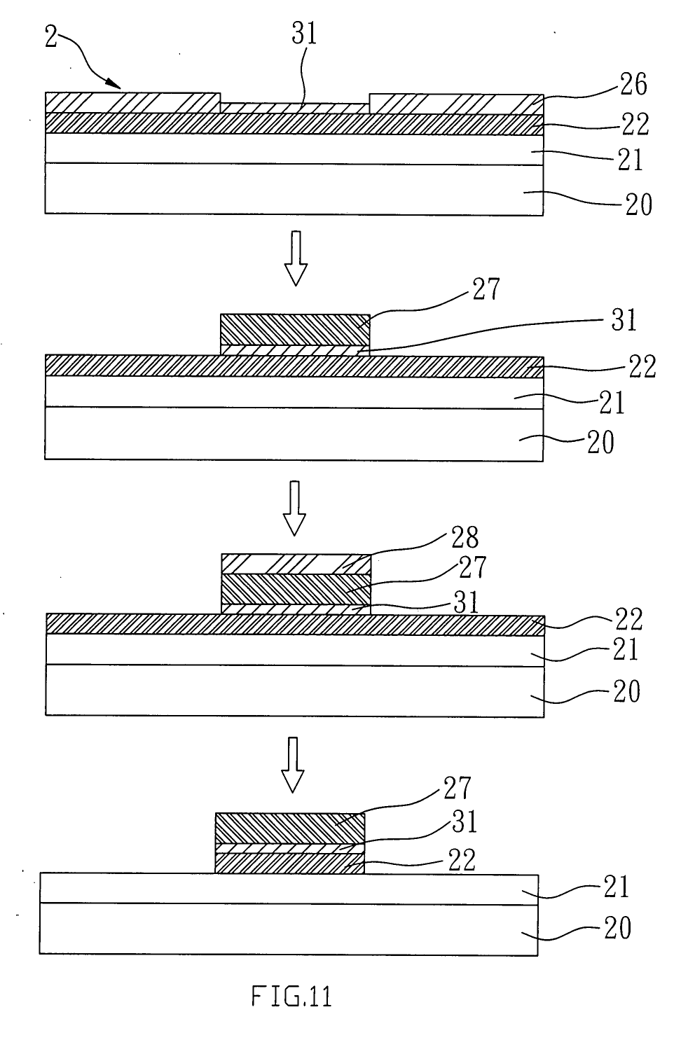

A fourth preferred embodiment of the present invention of a pad manufacturing process applied in LED epiwafer according to the process sequence as illustrated in FIG. 11 is related to a coated or deposited adhesion layer 31. As illustrated, the manufacturing process of the fourth preferred embodiment differs from that of the second preferred embodiment in that a photo resist mask 26 is formed on a fist metal layer 22 to define an exposed surface area E1; the adhesion layer 31 is coated (e.g., screen printing) or deposited by non-electrolytic plating or lift-off metallization process on the exposed surface area E1; a plated pad 27 is deposited on the adhesion layer 31; the first photo resist mask 26 is then removed; a second photo resist mask 28 in an inverse tone to the first photo resist mask 26 is formed on a third surface S3; the first metal layer 22 not screened by the second photo resist mask 28 and the pad 27 is removed in an etching process; and the second photo resist mask 28 is also removed to complete the pad manufacturing process of the fourth preferred embodiment of the present invention.

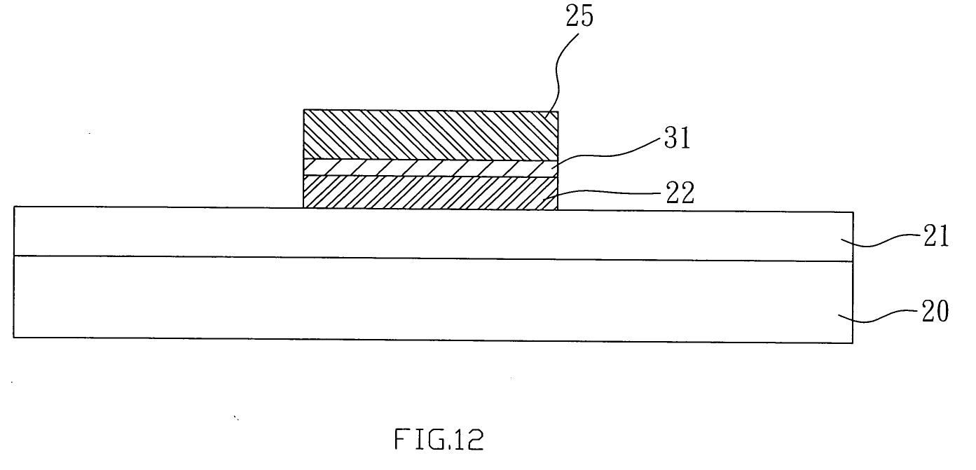

A new construction of epiwafer and a pad produced from applying the manufacturing process of the third or the fourth preferred embodiment of the present invention, as illustrated in FIG. 12, is comprised of an epiwafer 2 containing a substrate 20, an epitaxial layer 21, and a first metal layer covering the top of the epitaxial layer 21; an adhesion layer 31 covering the top of the first metal layer 22; and a pad 25 or 27 covering the top of the adhesion layer 31 in sequence.

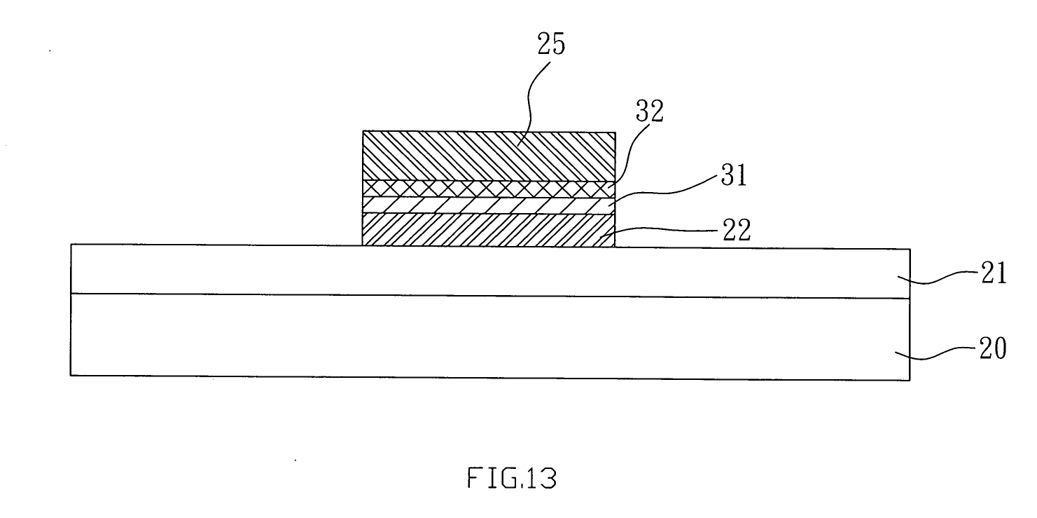

A fifth preferred embodiment is similar to the third preferred embodiment of the present invention. Wherein, a plating seed layer 32 is deposited on a blanket covering adhesion layer 31 before a second metal layer 25 is deposited. The remainder of the manufacturing process is the same as that disclosed in the third preferred embodiment to avail a final construction as illustrated in FIG. 13.

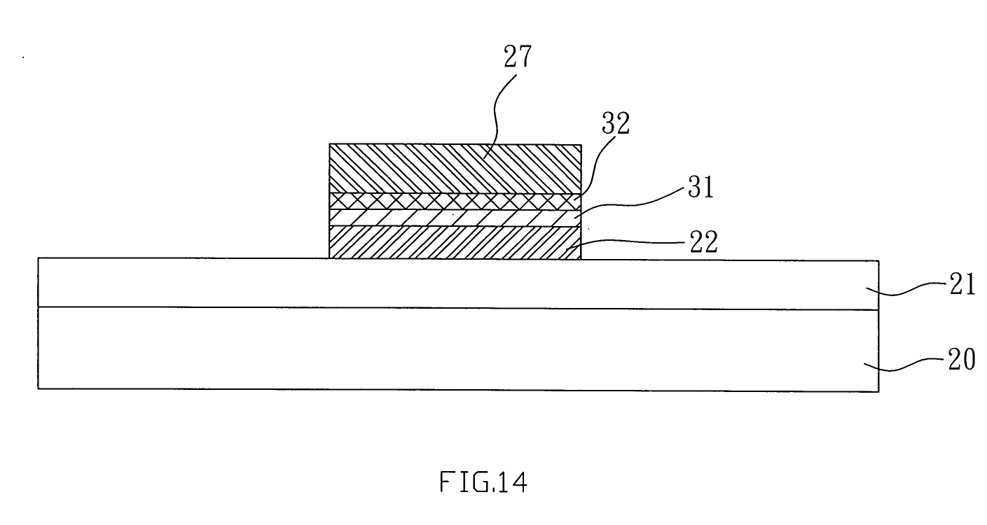

A sixth preferred embodiment is similar to the fourth preferred embodiment of the present invention. Wherein, a plating seed layer 32 is deposited on a patterned adhesion layer 31 after the adhesion layer pattern 31 is formed, and a pad is then deposited. The remainder of the manufacturing process is the same as that disclosed in the fourth preferred embodiment to avail a final construction as illustrated in FIG. 14.

The material of the plating seed layer 32 may be the same as that of the pad, e.g., gold. Another new construction of an epiwafer and a pad disclosed in the fifth and the six preferred embodiments of the present invention as illustrated in FIGS. 13 and 14 is comprised of an epiwafer 2 containing a substrate 20, an epitaxial layer 21, and a first metal layer 22 covering on top of the epitaxial layer 21; an adhesion layer 31 covering on top of the first metal layer 22; a plating seed layer 32 covering on top of an adhesion layer 31; and a pad 25 or 27 covering on top of the plating seed layer 32 in sequence.

Accordingly, in the present invention, a means to increase interfacial bonding strength is first applied to a first surface S1 of a first metal layer 22 of an epiwafer 2 or to an exposed surface area E1, and a pad is then deposited on the first surface S1 or the exposed surface area E1 to provide reliable adhesion between the pad and the epiwafer 2; and the excessive greater roughness of the pad surface (S2, S3) found with the prior art is corrected in the present invention by controlling plating conditions to obtain finer and more uniform grains deposition to improve the bonding strength between the pad and the bond wire.

It is to be noted that the preferred embodiments disclosed in the specification and the accompanying drawings are not limiting the present invention; and that any construction, installation, or characteristics that is same or similar to that of the present invention should fall within the scope of the purposes and claims of the present invention.

I claim:

1. A pad manufacturing process applied in LED epiwafer is comprised of the following steps:
(A) An epiwafer containing a substrate and a first metal layer is prepared;
(B) A first surface of the first metal layer is given a means to increase interfacial bonding strength;
(C) A second metal layer is deposited by a metal plating on the first surface; and
(D) A pad is patterned on the epiwafer using a photolithography technique

2. Another pad manufacturing process applied in LED epiwafer is comprised of the following steps:
(1) An epiwafer containing a substrate and a first metal layer is prepared;
(2) A first photo resist mask is formed on a first surface of the first metal layer to define an exposed surface area on the first surface;
(3) The exposed surface area is given a means to increase interfacial bonding strength;
(4) A second metal layer is deposited by a metal plating means on the exposed surface area;
(5) The first photo resist mask is removed, and a pad is form on the first surface;
(6) A second photo resist mask is formed on the pad; and
(7) The first metal layer not protected by the second photo resist mask and the pad is removed in an etching process.

3. The pad manufacturing process applied in LED epiwafer as claimed in claim 1, wherein the means to increase interfacial bonding strength is related to a plasma process.

4. The pad manufacturing process applied in LED epiwafer as claimed in claim 2, wherein n the means to increase interfacial bonding strength is related to a plasma process.

5. The pad manufacturing process applied in LED epiwafer as claimed in claim 1, wherein the means to increase interfacial bonding strength is related to wiping with ultra fine fiber yearns or woven fabric.

6. The pad manufacturing process applied in LED epiwafer as claimed in claim 2, wherein the means to increase interfacial bonding strength is related to wiping with ultra fine fiber yearns or woven fabric.

7. The pad manufacturing process applied in LED epiwafer as claimed in claim 1, wherein the means to increase interfacial bonding strength is related to soaking in or wiping with solvent or solution.

8. The pad manufacturing process applied in LED epiwafer as claimed in claim 2, wherein the means to increase interfacial bonding strength is related to soaking in or wiping with solvent or solution.

9. The pad manufacturing process applied in LED epiwafer as claimed in claim 1, wherein the metal deposition means relates to evaporation.

10. The pad manufacturing process applied in LED epiwafer as claimed in claim 2, wherein the metal deposition means relates to evaporation.

11. The pad manufacturing process applied in LED epiwafer as claimed in claim 1, wherein the metal deposition means relates to sputtering.

12. The pad manufacturing process applied in LED epiwafer as claimed in claim 2, wherein the metal deposition means relates to sputtering.

13. The pad manufacturing process applied in LED epiwafer as claimed in claim 1, wherein the metal deposition means relates to electroplating.

14. The pad manufacturing process applied in LED epiwafer as claimed in claim 2, wherein the metal deposition means relates to electroplating.

15. A pad manufacturing process applied in LED epiwafer is comprised of the following steps:
(A) An epiwafer containing a substrate and a first metal layer is prepared;
(B) A first surface of the first metal layer is given a plasma process;
(C) A second metal layer is deposited by electroplating on the first surface; and
(D) A pad is patterned on the epiwafer using a photolithography technique.

16. A pad manufacturing process applied in LED epiwafer is comprised of the following steps:
(1) An epiwafer containing a substrate and a first metal layer is prepared;
(2) A first photo resist mask is formed on a first surface of the first metal layer to define an exposed surface area on the first surface;
(3) The exposed surface area is given a plasma process;
(4) A second metal layer is deposited by a metal electroplating means on the exposed surface area;
(5) The first photo resist mask is removed, and a pad is form on the first surface;
(6) A second photo resist mask is formed on the pad; and
(7) The first metal layer not patterned by the second photo resist mask and the pad is removed in an etching process.

17. The pad manufacturing process applied in LED epiwafer as claimed in claim 15, wherein the plated deposition related to a gold plated deposition; the work temperature of the gold plated deposition ranging between 40˜50° C.; and
the work current density of the plated deposition ranging between 0.2˜0.5 Amp/dm².

18. The pad manufacturing process applied in LED epiwafer as claimed in claim 16, wherein the plated deposition related to a gold plated deposition; the work temperature of the gold plated deposition ranging between 40˜50° C.; and the work current density of the plated deposition ranging between 0.2˜0.5 Amp/dm².

19. A construction of LED epiwafer and pad includes an epiwafer containing a substrate and a first metal layer, an adhesion layer covering on top of the first metal layer, and a pad covering on top of the adhesion layer.

20. A construction of LED epiwafer and pad includes an epiwafer containing a substrate and a first metal layer; an adhesion layer covering on top of the first metal layer; a plating seed layer covering on top of the adhesion layer; and a pad covering on top of the plating seed layer.

21. The construction of LED epiwafer and pad as claimed in claim 20, wherein the plating seed layer and the pad are made of gold.

22. The construction of LED epiwafer and pad as claimed in claim 19, wherein the adhesion layer is related to a conductive metal or alloy.

23. The construction of LED epiwafer and pad as claimed in claim 20, wherein the adhesion layer is related to a conductive metal or alloy.
